(19) United States
(12) Patent Application Publication
(10) Pub. No.: US 2025/0073972 A1
(43) Pub. Date: Mar. 6, 2025

(54) INJECTION ASSEMBLY

(71) Applicant: HYUNDAI MOBIS CO., LTD., Seoul (KR)

(72) Inventor: Jun Seong SEO, Yongin-si (KR)

(73) Assignee: HYUNDAI MOBIS CO., LTD., Seoul (KR)

(21) Appl. No.: 18/426,553

(22) Filed: Jan. 30, 2024

(30) Foreign Application Priority Data
Sep. 4, 2023 (KR) 10-2023-0116772

(51) Int. Cl. B29C 45/77; B29C 45/22; B29C 45/26; B29C 45/27; B29C 45/74

(52) U.S. Cl. CPC B29C 45/77; B29C 45/22; B29C 45/2606; B29C 45/2737; B29C 45/278; B29C 45/74; B29C 2045/2743; B29C 2945/76006; B29C 2945/7621; B29C 2945/76381; B29C 2945/76545; B29C 2945/76688; B29C 2945/76859

(57) ABSTRACT

An injection assembly including a cover part which covers an upper surface of a controller and in which a plurality of injection holes are formed to correspond to positions of a plurality of heating elements and a nozzle unit including a plurality of nozzles to simultaneously inject an injection material into the plurality of injection holes, wherein a pressure sensor is disposed in each of the plurality of nozzles to measure an internal pressure of the nozzle and to control an injection speed based on the measured internal pressure.

### CROSS-REFERENCE TO RELATED APPLICATIONS

This application claims priority to and the benefit of Korean Patent Application No. 10-2023-0116772, filed on 4 Sep. 2023, the disclosure of which is incorporated herein by reference in its entirety.

### TECHNICAL FIELD

The present invention relates to an injection assembly, and more specifically, to an injection assembly which simultaneously injects and applies an injection material into and on a plurality of coating portions to shorten a processing time.

### BACKGROUND

Various types of controllers are mounted in vehicles, and chipsets with higher power consumption have recently been used for applying various high-performance functions. However, since the chipset with high power consumption generates a large amount of heat, it is important to emit heat to the outside.

Various types of thermal interface materials (TIMs) are applied to heating modules used inside the controllers. The TIM decreases thermal resistance between a heating element and a heat sink so that heat is smoothly transferred from the heating element to the heat sink to emit the heat to the outside of the controller.

Conventionally, the sandwich method, in which a heating chip and a mechanism are coated with a TIM before the chip and the mechanism are assembled and then the heating chip and the instrument are assembled, is applied. When the TIM is applied through such a method, TIM is pressed and force is applied to the chip sensitive to a pressure, and there are risks of damaging the chip and breaking a circuit board. Since a plurality of chips are used in the controller, the number of chips with which the TIM is coated increases, and when each chip is coated with the TIM, there is a problem that a process cycle increases. In order to solve these problems, studies on coating methods which shortens a coating time of the TIM and does not damage the chip and the circuit board have been conducted.

### SUMMARY

The present invention is directed to providing an injection module capable of simultaneously injecting and applying an injection material into and on a plurality of coating portions to shorten a processing time and using the injection material with a relatively low viscosity to prevent generation of an air layer so as to completely coat a coating surface with the injection material.

Objectives to be solved by the present invention are not limited to the above-described objectives, and other objectives which are not described above will be clearly understood by those skilled in the art from the following description.

According to an aspect of the present invention, there is provided an injection assembly including a cover part which covers an upper surface of a controller and in which a plurality of injection holes are formed to correspond to positions of a plurality of heating elements and a nozzle unit including a plurality of nozzles to simultaneously inject an injection material into the plurality of injection holes,

A pressure sensor may be disposed in each of the plurality of nozzles, measure an internal pressure of the nozzle, and control an injection speed.

A heat transfer part protruding from an upper side of the heating element toward the heating element may be formed in the cover part, an end of the heat transfer part and the heating element may be spaced a predetermined distance from each other, and the injection hole may be formed to pass through the heat transfer part.

When the injection material fills a space between the heat transfer part and the heating element, an injection speed of the injection material may be lowered or injection of the injection material may be stopped due to an increase in internal pressure of the nozzle detected by the pressure sensor.

A length of the nozzle is formed to be greater than a depth of the injection hole, and in a state in which an end of the nozzle is inserted into a lower end of the injection hole, the injection material may be injected.

A first rib which prevents the injection material from overflowing to a periphery portion of the heating element may be formed to protrude from an edge of the heat transfer part.

A guide groove may be formed in a surface of the heat transfer part facing the heating element, and the injection hole may be formed inside the guide groove.

A second rib which prevents a reverse flow of the injection material may be formed on an inner side surface of the injection hole.

According to another aspect of the present invention, there is provided an injection assembly in which a coagulant which solidifies an injection material to prevent a backflow of the injection material is disposed inside an injection hole.

According to still another aspect of the present invention, there is provided an injection assembly in which a guide part which guides an injection material in a direction perpendicular to a depth direction of an injection hole to prevent a heating element from being directly pressed is formed on an end of the injection hole.

The guide part may be formed between the end of the injection hole and the heating element to be parallel to an upper surface of the heating element, and at least a part of the guide part may be connected to the heat transfer part to guide the injection material to spread laterally.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a view illustrating a controller to which an injection assembly is applied according to one embodiment of the present invention;

FIG. 2 is a view illustrating a cover part of the injection assembly according to one embodiment of the present invention;

FIG. 3 is a cross-sectional view illustrating the injection assembly according to one embodiment of the present invention;

FIG. 4 is a view illustrating a heat transfer part according to one embodiment of the present invention;

FIG. 5 is a view illustrating a heat transfer part according to another embodiment of the present invention;

FIG. 6 shows views illustrating first ribs according to another embodiment of the present invention;

FIG. 7 is a view illustrating a second rib according to still another embodiment of the present invention;

FIG. 8 is a view illustrating a guide part according to yet another embodiment of the present invention; and

FIG. 9 is a cross-sectional view illustrating a guide part according to yet another embodiment of the present invention.

### DETAILED DESCRIPTION

Since the present invention may be variously modified and have several embodiments, specific embodiments will be illustrated in the accompanying drawings and described in detail. However, this is not intended to limit the present invention to the specific embodiments, and it should be appreciated that all changes, equivalents, and substitutes falling within the spirit and technical scope of the present invention are encompassed in the present invention. In the description of the embodiments, certain detailed descriptions of the related art will be omitted when it is deemed that they may unnecessarily obscure the gist of the inventive concept.

While the terms such as “first” and “second” may be used to describe various components, such components are not limited by the above terms. These terms are used only to distinguish one component from another.

Terminology used herein is only for the purpose of describing particular embodiments and is not intended to limit the present invention. The singular forms are intended to include the plural forms unless the context clearly indicates otherwise. In the present specification, it should be understood that the terms “comprise,” “comprising,” “include,” and/or “including” used herein specify the presence of stated features, numbers, steps, operations, elements, components, and/or combinations thereof but do not preclude the presence or addition of one or more other features, numbers, steps, operations, elements, components, and/or combinations thereof.

In addition, throughout the specification, when components are “connected,” this may not only mean that two or more components are directly connected, but this may also mean that two or more components are indirectly connected through other components or are physically connected as well as electrically connected, or are one thing even referred to as different names according to positions or functions thereof.

In addition, when a first component is described as being formed or disposed “on” or “under” a second component, such a description includes both a case in which the two components are formed or disposed in direct contact with each other and a case in which one or more other components are interposed between the two components. In addition, when the first component is described as being formed “on or under” the second component, such a description may include a case in which the first component is formed at an upper side or a lower side with respect to the second component.

Hereinafter, embodiments of an injection module will be described in detail with reference to the accompanying drawings, and when the embodiments are described with reference to the accompanying drawings, components which are the same or correspond to each other will be denoted by the same reference numerals, and redundant description thereof will be omitted.

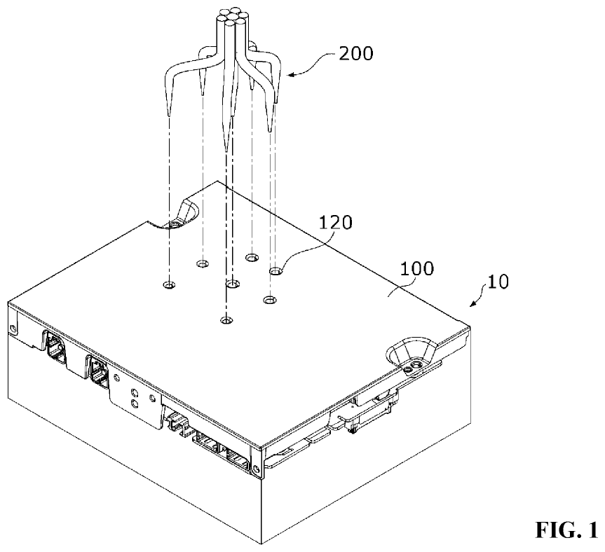

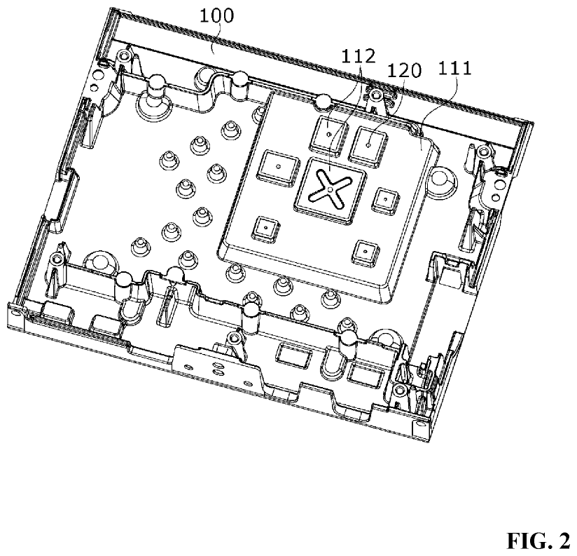

FIG. 1 is a view illustrating a controller to which an injection assembly is applied according to one embodiment of the present invention, and FIG. 2 is a view illustrating a cover part of the injection assembly according to one embodiment of the present invention.

Referring to FIGS. 1 and 2, the injection assembly according to one embodiment of the present invention may include a cover part 100, which covers an upper surface of the controller 10 and in which a plurality of injection holes 120 are formed to correspond to positions of a plurality of heating elements 20 (for example, chipsets in the controller), and a nozzle unit 200 including a plurality of nozzles 210 to simultaneously inject an injection material into the plurality of injection holes 120.

Various elements are provided in the controller 10 of a vehicle, a high-performance element is used to develop the high-performance controller 10, and there is a problem in dissipating heat generated by the corresponding chipset. In the case of the high-performance chipset, heat generated due to larger power consumption becomes larger than the conventional chipset, and thus it is important to emit the heat to the outside of the controller 10.

In the conventional controller 10, a sandwich method, in which before a process of assembling a cover part 100 of the controller 10, a coating surface of a heating element 20 is coated with a heat transfer material such as a gap filler and then the cover part 100 is assembled, is used. The gap filler fills a space between the heating element 20 and the cover part 100 and allows heat to be easily transferred.

However, since the plurality of heating elements 20 are provided in the controller 10, when each coating surface of the heating elements 20 is coated with the gap filler and then the cover part 100 is assembled, a coating time increases, and when coating is performed with a large amount of the gap filler, there is a concern that pressure is applied to the heating element 20 to break the heating element 20 in a process of assembling the cover part 100. When coating is performed with a very small amount of gap filler, the empty space may be generated between the heating element 20 and the cover part 100, heat transfer efficiency can be reduced, and thus heat cannot be easily dissipated.

The present invention may provide the injection assembly which may simultaneously inject an injection material into coating portions of the plurality of heating elements 20 and decrease a pressure applied to the heating element 20 to prevent damage to the controller 10.

As in FIG. 2, a first heat transfer part 111 formed to protrude from a region in which the heating element 20 is disposed may be formed inside the cover part 100. The first heat transfer part 111 may cover an upper surface above the entire region in which the heating element 20 is disposed and may fill a space above an upper surface of the heating element 20. A second heat transfer part 112 may be formed on an end of the first heat transfer part 111 corresponding to each of the heating elements 20. The second heat transfer part 112 may be formed to have any of various sizes to correspond to a size of the heating element 20, the injection material such as a gap filler may be applied into a space between the second heat transfer part 112 and the heating element 20 and may be in contact with the second heat transfer part 112 and the heating element 20 to allow heat to easily transfer between the heating element 20 and the cover part 100.

In the case of FIG. 2, it is illustrated that the second heat transfer part 112 has a rectangular shape, but the shape of the second heat transfer part 112 is not limited thereto, and may be formed to correspond to a shape of the heating element 20 covered by the second heat transfer part 112.

The cover part 100 including the first heat transfer part 111 and the second heat transfer part 112 may be formed of a material with a high heat transfer rate to easily transfer heat. As an example, the cover part 100 may be formed of an aluminum material to emit heat generated by the heating element 20 to the outside.

The plurality of injection holes 120 may be formed in the cover part 100 to correspond to positions of a plurality of coating portions. The injection holes 120 may be formed to pass through the first heat transfer part 111 and the second heat transfer part 112 and formed in the second heat transfer part 112 to allow the injection material to be injected into the space between the heating element 20 and the second heat transfer part 112.

Widths and shapes of the injection holes 120 may be different and may be differently set according to an amount of the injection material injected thereinto. As an example, in the case of an injection hole 120 formed in the small heating element 20 and formed in a portion in which an amount of the injection material is small, an inner diameter of the injection hole 120 may be small, and in the case of an injection hole 120 formed in the large heating element 20 and formed in a portion in which an amount of the injection material is large, the inner diameter of the injection hole 120 may be large.

The nozzle unit 200 may include the plurality of nozzles 210 having separate flow passages, and ends of the nozzles 210 may be formed to be bent. The plurality of nozzles 210 may be disposed in close contact with each other in a bundle type, and the ends are bent and disposed to be spaced apart from each other. The ends of the nozzles 210 may be formed to be bent and inserted into the injection holes 120 corresponding to positions of the nozzles 210.

The nozzle 210 may be formed not to be bent but formed to extend in a depth direction of the injection hole 120 at a position corresponding to the position of the injection holes 120 corresponding to each nozzle 210. The nozzles 210 may be spaced apart from each other by a distance equal to a gap between the injection holes 120. The plurality of nozzles 210 may be integrally fixed using a separate fixing part. As an example, the fixing part may be a plate provided with holes through which each nozzle 210 may pass. Each nozzle 210 may pass through the hole at corresponding position and may be fixedly integrated with the plate.

The nozzle unit 200 may be disposed above the upper surface of the controller 10 by a separate moving part, and then inserted into the injection hole 120. Since times for which the coating portions are completely filled with the injection material are different, a transfer part may move the nozzle unit 200 from the cover part 100 after the coating portion of which a coating time is greatest is completely coated with the injection material.

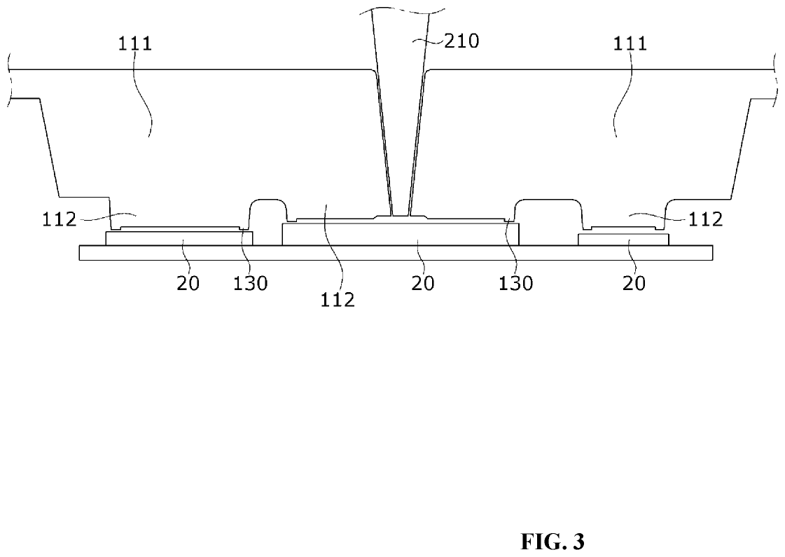

FIG. 3 is a cross-sectional view illustrating the injection assembly according to one embodiment of the present invention.

Referring to FIG. 3, it is illustrated that each nozzle 210 of the nozzle unit 200 is inserted into the injection hole 120. The nozzle 210 included in the nozzle unit 200 may be inserted into the injection hole 120 corresponding to the position of the nozzle 210 and simultaneously inject the injection material thereinto.

The nozzle 210 may be inserted into a lower end portion of the injection hole 120 in order to avoid the injection material from being applied on an inner side surface of the injection hole 120 or to avoid friction between the inner side surface and the injection material being injected. Accordingly, a length of the nozzle 210 may be greater than a depth of the injection hole 120.

Since the injection material is injected through the injection hole 120 in a state in which the cover part 100 is assembled, a low-viscosity material may be used as the injection material to be injected. In the case of the conventional sandwich method, since the cover part 100 is assembled after the coating portion is coated with the gap filler in advance, a high-viscosity material is used to prevent the gap filler from flowing downward. When the coating portion is coated through a method of injecting through the nozzle 210, the low-viscosity gap filler can be used because the injection material fills a limited space.

The space between the heating element 20 and the second heat transfer part 112 is filled with the injection material injected by the nozzle. In this case, a first rib 130 may be formed to protrude from an edge of the second heat transfer part 112 in order to prevent the injection material from overflowing to the outside of the heating element 20. The first rib 130 may be formed along the edge of the second heat transfer part 112 and may be a boundary for the coating portion with which the injection material is coated.

When the injection material is injected at a high pressure even after the injection material completely fills the space between the heating element 20 and the second heat transfer part 112, the heating element 20 sensitive to a pressure may be pressed and damaged, and the injection material may overflow to the outside of the heating element 20. In order to prevent these phenomena, an injection speed of the injection material needs to be controlled in each nozzle 210. A pressure sensor which measures an internal pressure of the nozzle 210 may be included inside the nozzle 210.

The pressure sensor may measure the internal pressure of the nozzle 210 and detect a pressure which increases when injection of the injection material is completed. When a pressure value measured by the pressure sensor greatly increases or increases to a value greater than or equal to a preset value, an injection speed of the corresponding nozzle 210 may be lowered or the injection may be stopped. Accordingly, the nozzle unit 200 may further include a control unit which receives the measured value from each pressure sensor and controls the operation of each nozzle 210.

Since the nozzle unit 200 includes the plurality of nozzles 210 forming the separate flow passages, the pressure sensor may be disposed in each of the nozzles 210 and may detect an internal pressure of the nozzles 210. Since specifications of coating portions may be different, filling amounts and filling speeds may be different, and thus individual control for the nozzle 210 is required, and the control unit may perform individual control on the nozzle 210 using a pressure value detected by the pressure sensor. The nozzle 210 for the coating portion completely filled with the injection material relatively quickly may stop injection more quickly than the other nozzles 210.

When the injection material starts to be injected into the coating portion, an internal pressure of the nozzle 210 maintains a constant level or linearly increases. When the injection material spreads over the coating portion and is sufficiently injected to reach a portion on which the first rib 130 corresponding to a boundary surface is formed, an internal pressure of the nozzle 210 rapidly increases from this time point. The pressure sensor may detect an increase in corresponding pressure, and the control unit may stop the injection of the nozzle 210 on the basis of a detected value of the pressure sensor.

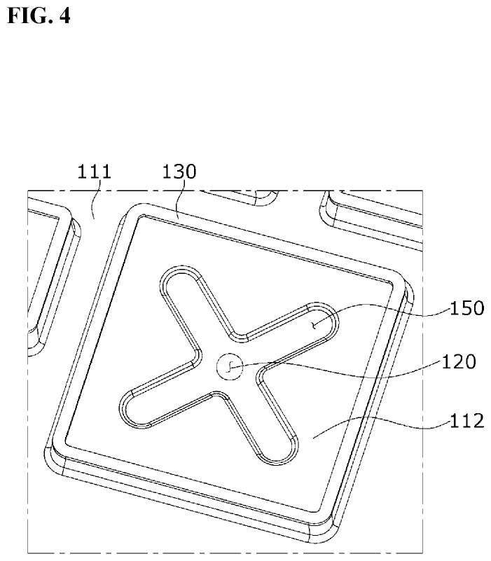

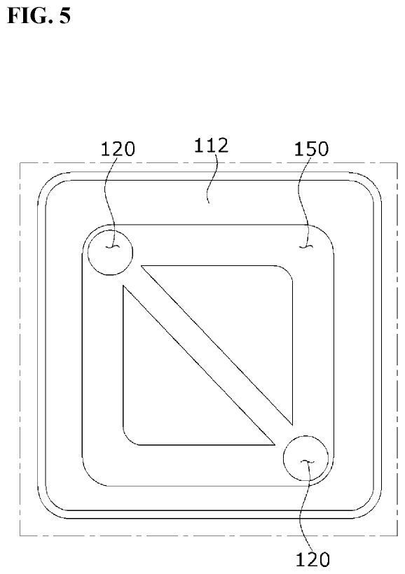

FIG. 4 is a view illustrating a heat transfer part according to one embodiment of the present invention, and FIG. 5 is a view illustrating a heat transfer part according to another embodiment of the present invention.

Referring to FIGS. 4 and 5, a guide groove 150 may be formed in a lower surface of a second heat transfer part 112. The guide groove 150 serves to guide an injection material injected through an injection hole 120 to be uniformly spread and applied on a coating portion. The guide groove 150 may be formed so that the injection hole 120 is positioned inside the guide groove 150.

The injection material such as a gap filler is a viscous material, and when coating is performed with the gap filler with a relatively high viscosity, the coating may be finished without completely filling an entire space between a heating element 20 and the second heat transfer part 112 due to resistance of viscosity. When the gap filler with a relatively low viscosity is used, the injection material may easily flow, and thus all area of a coating portion can be uniformly coated.

The guide groove 150 is formed in the lower surface of the second heat transfer part 112 by recessing at least a part of the lower surface of the second heat transfer part 112. The guide groove 150 may be formed to extend toward edges and corners to which the injection material may not move easily. Since an area in which the injection material moves relatively increases in a portion in which the guide groove 150 is formed, and thus the injection material can easily flow even when there is resistance due to the viscosity of the injection material.

A shape of the guide groove 150 is not limited, and as in FIG. 4, the guide groove 150 may be formed in a cross shape extending toward four vertexes of the coating portion from the injection hole 120 disposed at the center thereof. Alternatively, the guide groove 150 may be formed to extend in a radial direction so that the injection material spreads in the radial direction from the injection hole 120 and may be formed in a circular shape around the injection hole 120.

The injection hole 120 may be provided as a plurality of injection holes 120 in each coating portion. Referring to FIG. 5, two injection holes 120 are formed in the second heat transfer part 112 disposed on one heating element 20.

Shapes of heating elements 20 are different, and in the case of sizes of the heating elements 20 are great, an area of coating portions are wide and should be coated with a large amount of the injection material. In this case, a plurality of injection holes 120 may be formed in the second heat transfer part 112 which covers the corresponding heating elements 20 to increase a coating speed and also uniformly coat all portions with the injection material without a missing portion.

When the plurality of injection holes 120 are formed in the second heat transfer part 112, the injection holes 120 may be connected through the guide groove 150. As in FIG. 5, when two injection holes 120 are formed, each of the injection holes 120 may be connected to the guide groove 150, and the guide groove 150 may be formed so that the injection material is injected into a space between the injection holes 120 and injected onto edge portions of the heating element 20.

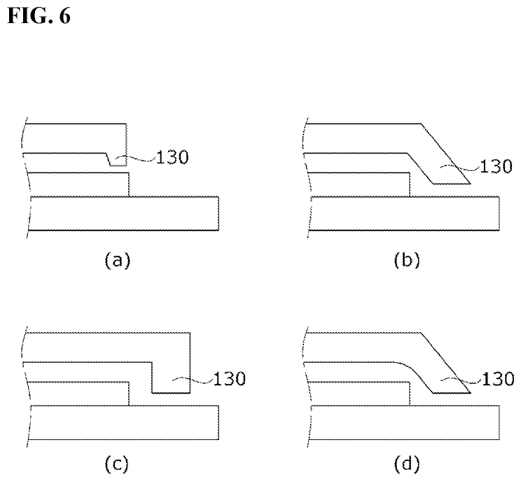

FIG. 6 shows views illustrating first ribs according to another embodiment of the present invention.

Referring to FIG. 6, a first rib 130 may be formed to protrude from an edge portion of a heating element 20 and disposed at a predetermined distance from the heating element 20.

The first rib 130 serves to prevent an injection material filling a space between the heating element 20 and a second heat transfer part 112 from overflowing to the outside of the heating element 20. The first rib 130 is formed on a surface of the second heat transfer part 112 facing the heating element 20 to protrude from an edge portion of the second heat transfer part 112. In this case, the first rib 130 and the heating element 20 may be disposed to be spaced a predetermined distance from each other, this is for allowing air filling the space between the second heat transfer part 112 and the heating element 20 to be discharged to the outside while the injection material is injected into and fills the corresponding space. In addition, when a cover part 100 is assembled, a pressure can be prevented from being directly applied to the heating element 20.

Although the first rib 130 may be disposed at the predetermined distance from the heating element 20 to allow the air to be discharged as described above, but alternatively, the first rib 130 may be formed to protrude from only at least a part of the edge portion of the second heat transfer part 112. An air hole may be formed in the first rib 130 to discharge air in a horizontal direction.

A shape of the first rib 130 is not limited, and any shape may be applied as long as preventing the injection material from overflowing to the outside of the heating element 20. As in (a) in FIG. 6, a first rib 130 may be formed to protrude downward from an edge portion of a second heat transfer part 112, and as in (b) in FIG. 6, a first rib 130 may be formed to protrude to be inclined from an edge portion of a second heat transfer part 112 toward the outside of a heating element 20. In this case, as in (d) in FIG. 6, a bent portion may be formed as a curved surface to remove resistance against a flow of an injection material and prevent pressurizing due to injection of the injection material. Alternatively, as in (c) in FIG. 6, a first rib 130 may be formed to protrude at a predetermined distance away toward the outside of a heating element 20. The first rib 130 in (c) in FIG. 6 may be applied when there is no problem in operation of a circuit even when the outside of a heating element 20 is coated with a certain amount of an injection material.

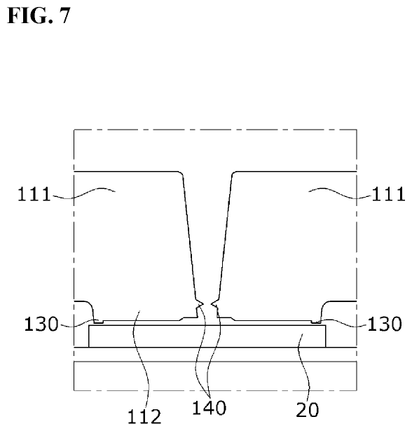

FIG. 7 is a view illustrating a second rib according to still another embodiment of the present invention.

Referring to FIG. 7, a second rib 140 for preventing a backflow of an injection material may be formed inside an injection hole 120. Since the injection material is injected through a nozzle, when the injection material completely fills a space between a heating element 20 and a second heat transfer part 112, the injection material may backflow toward the injection hole 120. In order to prevent the backflow, the second rib 140 formed to protrude may be formed inside the injection hole 120.

As illustrated in the drawing, the second rib 140 may be formed to protrude along an inner circumference of the injection hole 120 and formed of the same material as a cover part 100 and a first heat transfer part 111. Alternatively, the second rib 140 may be formed of a material different from a material of the cover part 100.

As an example, the second rib 140 may be formed of a material such as rubber so as not to interfere with the nozzle when the nozzle enters or exits the injection hole 120. When the second rib 140 is formed of the material such as the rubber, the second rib 140 may be bent in a movement direction of the nozzle and may prevent a backflow in a method of blocking a periphery portion of the nozzle when the nozzle enters or exits the injection hole 120.

A coagulant may be disposed without forming the second rib 140. When a predetermined amount of the coagulant is disposed inside the injection hole 120, and the injection material flows back into the injection hole 120, the injection material reacts with the coagulant and the injection material is solidified to prevent a backflow. Different types of coagulants may be applied according to types of injection materials.

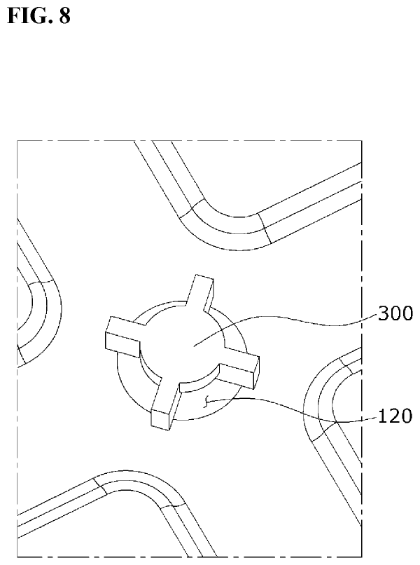

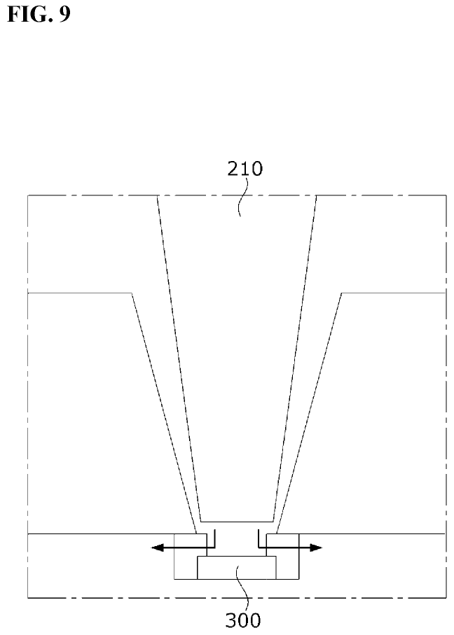

FIG. 8 is a view illustrating a guide part according to yet another embodiment of the present invention, and FIG. 9 is a cross-sectional view illustrating the guide part according to yet another embodiment of the present invention.

Referring to FIGS. 8 and 9, in an injection module according to yet another embodiment of the present invention, a guide part 300 which guides an injection material in a direction perpendicular to a depth direction of an injection hole 120 may be formed.

Since a heating element 20 is sensitive to a pressure, the heating element 20 needs to be prevented from being pressed. The nozzle 210 is inserted into the injection hole 120, and a portion with which the injection material comes into first contact is an upper surface of the heating element 20 when the injection material is injected from the nozzle 210. In this case, a pressure may be applied to the heating element 20 by the injection material, and when an injection speed is high, the heating element 20 may be damaged due to the high pressure.

The guide part 300 is formed at an end of the injection hole 120, comes into first contact with the injection material, and guides the injection material to flow in a horizontal direction. The guide part 300 may be formed at the end of the injection hole 120 to be parallel to the upper surface of the heating element 20, and at least a part of a portion formed parallel thereto may be fixedly connected to a second heat transfer part 112.

As in FIG. 9, at least a part of the guide part 300 is fixedly connected to the second heat transfer part 112. The guide part 300 positioned at an entrance of a nozzle 210 guides the injection material injected by the nozzle 210 to spread along the portion formed parallel to the upper surface of the heating element 20 in the horizontal direction and prevents the heating element 20 from being directly pressed. A shape of the guide part 300 is not limited, and any shape which prevents the heating element 20 from being directly pressed may be applied thereto.

According to one embodiment of the present invention, after a cover part which covers an upper portion of a heating element and in which a plurality of injection holes are formed is assembled, a nozzle unit including a plurality of nozzles can be inserted into the plurality of injection holes to simultaneously inject an injection material into the plurality of injection holes so that the injection material is simultaneously injected into a plurality of heating elements, thereby shortening a coating time, and it is possible to inject the injection material into each coating portion without the generation of an air layer.

Various useful beneficial advantages and effects of the present invention are not limited to the above-described content and will be more easily understood in the above detailed description of specific embodiments of the present invention.

While the present invention has been described above with reference to specific embodiments, it may be understood by those skilled in the art that various modifications and changes of the present invention may be made within a range not departing from the spirit and scope of the present invention defined by the appended claims.

What is claimed is:

1. An injection assembly comprising:
a cover part configured to cover an upper surface of a controller, a plurality of injection holes being formed in the cover part to correspond respectively to positions of a plurality of heating elements in the controller; and
a nozzle unit including a plurality of nozzles configured to simultaneously inject an injection material into the plurality of injection holes in the cover part of the controller,
wherein:
a plurality of pressure sensors are disposed respectively in the plurality of nozzles so that each of the plurality of nozzles includes one of the pressure sensors, and
each of the plurality of pressure sensors is configured to measure an internal pressure of a corresponding nozzle in which it is located and to control an injection speed of the injection material into a corresponding injection hole adjacent to which the nozzle is positioned based upon the measured internal pressure.

2. The injection assembly of claim 1, further comprising:
a first heat transfer part configured to cover a region of the controller in which the plurality of heating elements are formed and to protrude toward the cover part;
a second heat transfer part on a lower end portion of the first heat transfer part, protruding from the lower end portion of the first heat transfer part and corresponding to a size of each of the plurality of heating elements;
wherein:
an end of the second heat transfer part and at least one of the heating elements are spaced apart from each other by a predetermined distance; and
the injection holes are formed to pass through the first heat transfer part and the second heat transfer part.

3. The injection assembly of claim 2, wherein, when the injection material fills a space between the second heat transfer part and the at least one of the heating elements, an injection speed of the injection material is lowered or stopped based on an increase in internal pressure of the corresponding nozzle detected by the pressure sensor in the corresponding nozzle.

4. The injection assembly of claim 3, wherein:
a length of each of the nozzles is greater than a depth of the corresponding injection hole located adjacent to the nozzle; and
in a state in which an end of the nozzle is inserted into a lower end of the corresponding injection hole, the injection material is injected.

5. The injection assembly of claim 4, including a first rib configured to prevent the injection material from overflowing to a periphery portion of the at least one of the heating elements that protrudes from an edge of the second heat transfer part.

6. The injection assembly of claim 5, wherein:
a guide groove is formed in a surface of the second heat transfer part facing the at least one of the heating elements; and
the corresponding injection hole is formed inside the guide groove.

7. The injection assembly of claim 6, wherein a second rib configured to prevent a backflow of the injection material is located on an inner side surface of the corresponding injection hole.

8. The injection assembly of claim 6, wherein a coagulant configured to solidify the injection material to prevent a backflow of the injection material is disposed inside the corresponding injection hole.

9. The injection assembly of claim 6, wherein a guide part is located to guide the injection material in a direction perpendicular to a depth direction of the corresponding injection hole to prevent the at least one of the heating elements from being directly pressed is located on an end of the corresponding injection hole.

10. The injection assembly of claim 9, wherein:
the guide part located between the end of the corresponding injection hole and the at least one of the heating elements is parallel to an upper surface of the at least one of the heating elements; and
at least a part of the guide part is connected to the second heat transfer part to guide the injection material to spread to a side surface of the second heat transfer part.

11. The injection assembly of claim 1, wherein the heating element is a chipset inside the controller.
